(19) United States
(12) Patent Application Publication
(10) Pub. No.: US 2022/0415988 A1
(43) Pub. Date: Dec. 29, 2022

(54) DISPLAY DEVICE

(71) Applicant: Japan Display Inc., Tokyo (JP)

(72) Inventors: Masanobu IKEDA, Tokyo (JP); Yasuhiro KANAYA, Tokyo (JP); Takumi SANO, Tokyo (JP); Yasushi KAWATA, Tokyo (JP)

(21) Appl. No.: 17/882,706

(22) Filed: Aug. 8, 2022

Related U.S. Application Data
(63) Continuation of application No. PCT/JP2020/045353, filed on Dec. 4, 2020.

(30) Foreign Application Priority Data
Feb. 10, 2020 (JP) 2020-020754

(51) Int. Cl. H01L 27/32

(52) U.S. Cl. CPC H01L 27/3262; H01L 27/3276

(57) ABSTRACT

According to one embodiment, a display device comprises an insulating base, a plurality of light-emitting elements, a plurality of pixel circuits, and a plurality of lines. The insulating base includes a plurality of first island portions and a plurality of non-linear line portions connecting two of the first island portions. The light-emitting elements are arranged in each of the first island portions. The pixel circuits are arranged in each of the first island portions and driving the light-emitting elements. The lines are arranged in each of the line portions and connected to the pixel circuits of the two first island portions connected by the line portions.

### CROSS-REFERENCE TO RELATED APPLICATIONS

This application is a Continuation Application of PCT Application No. PCT/JP2020/045353 filed Dec. 4, 2020 and based upon and claiming the benefit of priority from Japanese Patent Application No. 2020-020754, filed Feb. 10, 2020, the entire contents of all of which are incorporated herein by reference.

### FIELD

Embodiments described herein relate generally to display devices.

### BACKGROUND

In recent years, flexible display devices with display elements arranged in a resin substrate have been developed. Since the screen can be bent in this type of display device, new electronic device designs and display device applications can be realized.

On the other hand, since conventional flexible display devices do not have elasticity, it has been difficult to deform them into, for example, a spherical surface or other three-dimensional curved surfaces.

### BRIEF DESCRIPTION OF THE DRAWINGS

FIG. 1 is a schematic perspective view of a display device according to a first embodiment.

FIG. 2 is a schematic circuit diagram of a display panel included in the display device.

FIG. 3 is a schematic plan view showing a part of an insulating base included in the display panel in an enlarged manner.

FIG. 4 shows an example of an equivalent circuit of a sub-pixel included in the display panel.

FIG. 5 is a schematic cross-sectional view of the display panel.

FIG. 6 is a schematic cross-sectional view of a part of the display panel including a line portion.

FIG. 7 is a schematic plan view of some elements included in the pixel.

FIG. 8 is a schematic plan view of other elements included in the pixel.

FIG. 9 is a schematic plan view showing a part of an insulating base in a non-display area of the display panel in an enlarged manner.

FIG. 10 is a schematic plan view showing an example of a structure of a scanning driver included in the display panel.

FIG. 11 shows an example of an equivalent circuit of a sub-pixel according to a second embodiment.

FIG. 12 is a schematic cross-sectional view of a display panel according to the second embodiment.

FIG. 13 is a schematic plan view of elements included in a pixel included in the display panel.

FIG. 14 is a schematic plan view of other elements included in the pixel.

FIG. 15 is a schematic plan view of other elements included in the pixel.

FIG. 16 is a schematic plan view of a pixel according to a third embodiment.

FIG. 17 is a schematic plan view of a pixel according to a fourth embodiment.

### DETAILED DESCRIPTION

In general, according to one embodiment, a display device comprises an insulating base, a plurality of light-emitting elements, a plurality of pixel circuits, and a plurality of lines. The insulating base includes a plurality of first island portions and a plurality of non-linear line portions connecting two of the first island portions. The light-emitting elements are arranged in each of the first island portions. The pixel circuits are arranged in each of the first island portions and driving the light-emitting elements. The lines are arranged in each of the line portions and connected to the pixel circuits of the two first island portions connected by the line portions.

According to such structure, a display device having elasticity is provided.

Embodiments will be described hereinafter with reference to the accompanying drawings.

The disclosure is merely an example, and proper changes within the spirit of the invention, which are easily conceivable by a skilled person, are included in the scope of the invention as a matter of course. In addition, in some cases, in order to make the description clearer, the widths, thicknesses, shapes, etc., of the respective parts are schematically illustrated in the drawings, compared to the actual modes. However, the schematic illustration is merely an example, and adds no restrictions to the interpretation of the invention. Besides, in the specification and drawings, the same or similar elements as or to those described in connection with preceding drawings or those exhibiting similar functions are denoted by like reference numerals, and a detailed description thereof is omitted unless otherwise necessary.

Each embodiment discloses, as an example, a self-luminous display device comprising an LED (light-emitting diode) element. However, each embodiment does not preclude the application of individual technical ideas disclosed in each embodiment to other types of display devices.

For example, at least a part of the configuration disclosed in each embodiment is also applicable to a display device comprising an organic electroluminescent element, an electronic paper-type display device having an electrophoretic element, a display device applying a micro-electromechanical system (MEMS), or a display device applying electrochromism, etc.

### First Embodiment

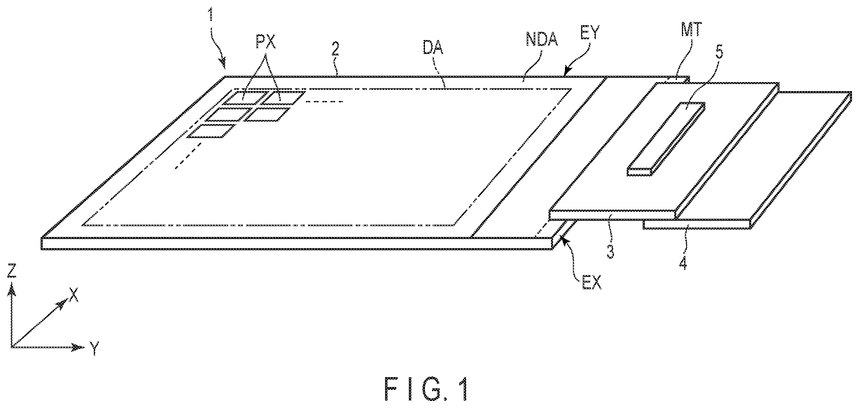

FIG. 1 is a schematic perspective view of a display device 1 according to a first embodiment. In the following description, a first direction X, a second direction Y, and a third direction Z are as defined in the drawing. These directions X, Y, and Z are orthogonal to each other, but may intersect at an angle other than 90°. In the present embodiment, a view of the display device 1 and its components along the third direction Z is referred to as a plan view. The third direction Z may also be referred to as above, and an opposite direction of the third direction Z may be referred to as below.

The display device 1 comprises a display panel 2, a first circuit board 3, a second circuit board 4, and a controller 5. In the example of FIG. 1, the display panel 2 has a rectangular shape with a short side EX parallel to the first direction X and a long side EY parallel to the second direction Y. The third direction Z corresponds to a thickness direction of the display panel 2.

The display panel 2 includes a display area DA in which an image is displayed and a non-display area NDA (peripheral area) around the display area DA. The non-display area NDA includes a terminal area MT along the short side EX. Although the display area DA is rectangular in the present embodiment, the display area DA may also be in other shapes. In the display area DA, a plurality of pixels PX are arranged in a matrix in the first direction X and the second direction Y.

The first circuit board 3 is mounted on the terminal area MT and electrically connected to the display panel 2. The second circuit board 4 is electrically connected to the first circuit board 3. The first circuit board 3 is, for example, a flexible circuit board (FPC). The second circuit board 4 is, for example, a printed circuit board (PCB). The controller 5 is, for example, an integrated circuit (IC). In the example of FIG. 1, the controller 5 is mounted on the first circuit board 3. However, controller 5 may also be mounted under the first circuit board 3, in the non-display area NDA, or on the second circuit board 4.

The controller 5 is connected to a control board (not shown) via, for example, the second circuit board 4. The controller 5 drives a plurality of pixels PX based on video signals output from the control board.

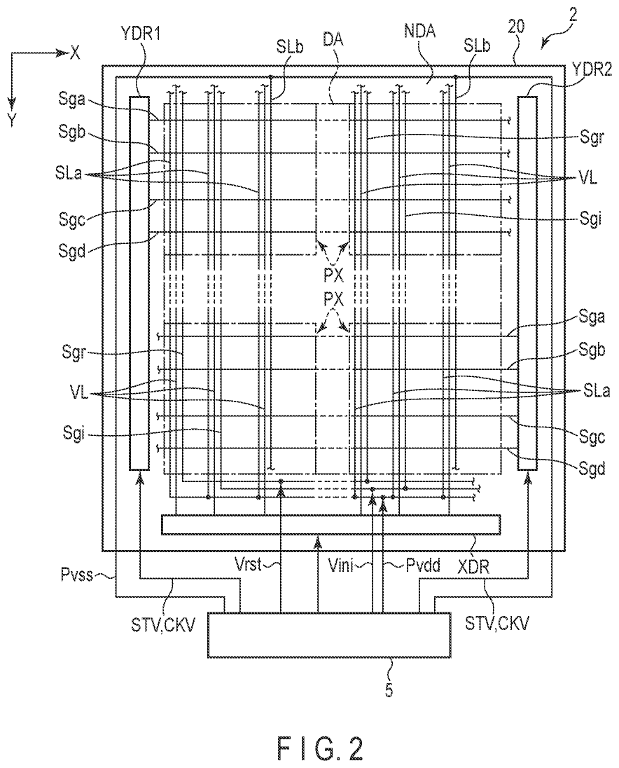

FIG. 2 is a schematic circuit diagram of the display panel 2 according to the present embodiment. The display panel 2 comprises a video driver XDR, a first scanning driver YDR1, and a second scanning driver YDR2 in the non-display area NDA. The video driver XDR extends in the first direction X. The scanning drivers YDR1 and YDR2 extend in the second direction Y. The display area DA is located between the scanning drivers YDR1 and YDR2.

The display panel 2 comprises multiple types of lines. These lines include a plurality of first scanning lines Sga, a plurality of second scanning lines Sgb, a plurality of third scanning lines Sgc, a plurality of fourth scanning lines Sgd, a plurality of video signal lines VL, a plurality of first power supply lines SLa, a plurality of second power supply lines SLb, a plurality of reset lines Sgr, and a plurality of initialization lines Sgi.

The scanning lines Sga, Sgb, Sgc, and Sgd extend in the first direction X and are connected to the scanning drivers YDR1 and YDR2. For example, the scanning lines Sga, Sgb, Sgc, and Sgd for driving even-numbered pixels PX among the pixels PX lined up in the second direction Y are connected to the first scanning driver YDR1, and the scanning lines Sga, Sgb, Sgc, and Sgd for driving odd-numbered pixels PX among the pixels PX lined up in the second direction Y are connected to the second scanning driver YDR2. As another example, for example, all of the scanning lines Sga and Sgb may be connected to the first scanning driver YDR1 and all of the scanning lines Sgc and Sgd may be connected to the second scanning driver YDR2. That is, one of the scanning lines Sga, Sgb, Sgc, and Sgd may be connected to the first scanning driver YDR1 and the rest may be connected to the second scanning driver YDR2.

The video signal line VL, the first power supply line SLa, the second power supply line SLb, the reset line Sgr, and the initialization line Sgi extend in the second direction Y. The video signal line VL is connected to the video driver XDR. A high potential Pvdd is supplied to the first power supply line SLa from the controller 5. A low potential Pvss, which is lower than the high potential Pvdd, is supplied to the second power supply line SLb from the controller 5. A reset potential Vrst is supplied to the reset line Sgr from the controller 5. An initialization potential Vini is supplied to the initialization line Sgi from the controller 5.

The controller 5 outputs a start pulse signal STV and a clock signal CKV to the scanning drivers YDR1 and YDR2. The scanning drivers YDR1 and YDR2 include a plurality of shift register circuits, sequentially transfer the start pulse signal STV to a shift register circuit in the next stage according to the clock signal CKV, and sequentially supply a scan signal to each of the scanning lines Sga, Sgb, Sgc, and Sgd.

The display panel 2 comprises a flexible insulating base (insulating substrate) 20. The video driver XDR, the scanning drivers YDR1 and YDR2, the scanning lines Sga, Sgb, Sgc, and Sgd, the video signal lines VL, the power supply lines SLa and SLb, the reset lines Sgr, the initialization lines Sgi, and the pixels PX, etc., shown in FIG. 2 are disposed on the insulating base 20.

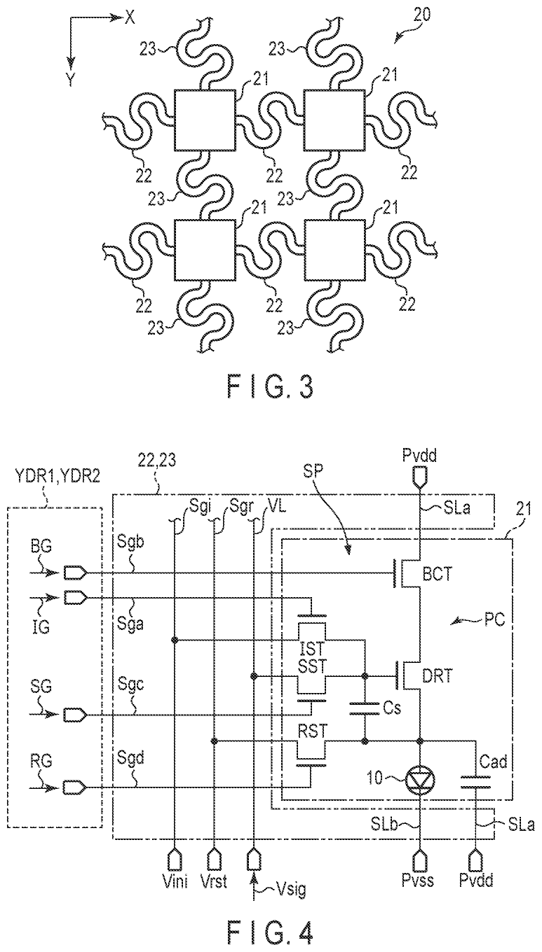

FIG. 3 is a schematic plan view showing a part of the insulating base 20 in an enlarged manner. The insulating base 20 has a plurality of island portions 21. The island portions 21 are arranged in a matrix in the first direction X and the second direction Y. In the example of FIG. 3, the island portions 21 are square, but may also be other shapes such as rectangular, rhombic, an accurate circle or oval. The pitch of the island portions 21 lined up in the first direction X and the pitch of the island portions 21 lined up in the second direction Y are the same, but may also be different.

The insulating base 20 also includes a plurality of first line portions 22 and a plurality of second line portions 23. The first line portions 22 connect two island portions 21 adjacent in the first direction X. The second line portions 23 connect two island portions 21 adjacent in the second direction Y. In the example of FIG. 3, the line portions 22 and 23 are each connected to a linear side of the island portion 21. As another example, the line portions 22 and 23 may be connected to corners of the island portion 21.

The line portions 22 and 23 are both non-linear. In the example of FIG. 3, the line portions 22 and 23 are largely bent twice and have an S-shaped meandering shape as a whole. Such a shape is sometimes called a meander pattern. However, the shape of the line portions 22 and 23 is not limited to the example in FIG. 3, and may be various shapes, such as a shape that bends only once or three or more times. The shapes of the first line portion 22 and the second line portion 23 may also be different.

The insulating base 20 is formed of, for example, polyimide. In this case, each island portion 21 and each of the line portions 22 and 23 can be formed integrally by patterning a polyimide film. Note that the material of the insulating base 20 is not limited to polyimide and can be other resin materials.

By configuring the insulating base 20 in this manner with a plurality of island portions 21 and the non-linear line portions 22 and 23 connecting these island portions 21, the insulating base 20 and the display panel 2 can be given flexibility and elasticity. In other words, when tension or compression force is applied to the display panel 2 in a specific direction, the line portions 22 and 23 expand and contract in response to this tension or compression force. This causes the display panel 2 to deform into a shape in response to the tension or compression force.

In the present embodiment, in both the display area DA and non-display area NDA, the insulating base 20 has the pattern shown in FIG. 3. However, in some parts of the display area DA and non-display area NDA, the insulating base 20 may have other shapes such as a uniform plate shape.

FIG. 4 shows an example of an equivalent circuit of a sub-pixel SP included in the pixel PX. The sub-pixel SP comprises a light-emitting element 10 and a pixel circuit PC that drives the light-emitting element 10. In the present embodiment, a case in which the light-emitting element 10 is a micro light emitting diode (micro LED) is assumed. In other words, the display device 1 is a micro-LED display device.

As an example, in the light-emitting element 10 that is a micro LED, the length of the longest side is 100 μm or less. However, the light-emitting element 10 may also be a mini-LED whose longest side has a length of, for example, more than 100 μm and less than 300 μm. The light-emitting element 10 may also be an LED having the longest side length of 300 μm or more.

The pixel circuit PC controls the light-emitting element 10 according to a video signal Vsig supplied to the video signal line VL. To realize such control, the pixel circuit PC in the present embodiment comprises a reset switch RST, a pixel switch SST, an initialization switch IST, an output switch BCT, a drive transistor DRT, a holding capacitance Cs, and an auxiliary capacitance Cad. The auxiliary capacitance Cad is an element provided to adjust the amount of luminous current and may be unnecessary in some cases.

The reset switch RST, the pixel switch SST, the initialization switch IST, the output switch BCT, and the drive transistor DRT are configured by a thin-film transistor (TFT). The reset switch RST, the pixel switch SST, the initialization switch IST, the output switch BCT, and the drive transistor DRT can be configured by, for example, an N-channel TFT; however, at least one of them may also be configured by a P-channel TFT.

In the present embodiment, the reset switch RST, the pixel switch SST, the initialization switch IST, the output switch BCT, and the drive transistor DRT are thin-film transistors with a top-gate structure formed by the same process and the same layer structure and using polycrystalline silicon as the semiconductor layer. Alternatively, the reset switch RST, the pixel switch SST, the initialization switch IST, the output switch BCT, and the drive transistor DRT may be thin-film transistors with a bottom-gate structure. Note that oxide semiconductors or polycrystalline GaN semiconductors may be used as the semiconductor layer.

The reset switch RST, the pixel switch SST, the initialization switch IST, the output switch BCT, and the drive transistor DRT has a first terminal, a second terminal, and a control terminal. In the present embodiment, the first terminal is called a source electrode, the second terminal is called a drain electrode, and the control terminal is called a gate electrode.

The drive transistor DRT and the output switch BCT are connected in series with the light-emitting element 10 between the first power supply line SLa and the second power supply line SLb. The first power supply line SLa (high potential Pvdd) is set to, for example, 10 V, and the second power supply line SLb (low potential Pvss) is set to, for example, 1.5 V.

The drain electrode of the output switch BCT is connected to the first power supply line SLa. The source electrode of the output switch BCT is connected to the drain electrode of the drive transistor DRT. The gate electrode of the output switch BCT is connected to the second scanning line Sgb. As a result, the output switch BCT is turned ON and OFF by a control signal BG provided to the second scanning line Sgb. Here, ON represents a conducting state, and OFF represents a non-conducting state. The output switch BCT controls the luminous time of the light-emitting element 10 based on the control signal BG.

The source electrode of the drive transistor DRT is connected to one electrode (here, an anode) of the light-emitting element 10. The other electrode of the light-emitting element 10 (here, a cathode) is connected to the second power supply line SLb. The drive transistor DRT outputs a drive current corresponding to the video signal Vsig to the light-emitting element 10.

The source electrode of the pixel switch SST is connected to the video signal line VL. The drain electrode of the pixel switch SST is connected to the gate electrode of the drive transistor DRT. The gate electrode of the pixel switch SST is connected to the third scanning line Sgc that functions as a gate line for a signal writing control. The pixel switch SST is turned ON and OFF by the control signal SG supplied from the third scanning line Sgc, and switches between connection and disconnection between the pixel circuit PC and the video signal line VL. In other words, when the pixel switch SST is turned ON, the video signal Vsig of the video signal line VL is taken into the pixel circuit PC.

The source electrode of the initialization switch IST is connected to the initialization line Sgi. The drain electrode of the initialization switch IST is connected to the gate electrode of the drive transistor DRT. The gate electrode of the initialization switch IST is connected to the first scanning line Sga. The initialization switch IST is turned ON and OFF by the control signal IG supplied from the first scanning line Sga, and switches between connection and disconnection between the pixel circuit PC and the initialization line Sgi. In other words, when the initialization switch IST is turned ON, the initialization potential Vini of the initialization line Sgi is taken into the pixel circuit PC.

The source electrode of the reset switch RST is connected to the reset line Sgr. The gate electrode of the reset switch RST is connected to the fourth scanning line Sgd that functions as a gate line for a reset control. The reset switch RST is turned ON and OFF by the control signal RG supplied from the fourth scanning line Sgd. When the reset switch RST is turned ON, the potential of the source electrode of the drive transistor DRT can be reset to the reset potential Vrst of the reset line Sgr.

The holding capacitance Cs is connected between the gate electrode and the source electrode of the drive transistor DRT. The auxiliary capacitance Cad is connected between the source electrode of the drive transistor DRT and the first power supply line SLa.

In the configuration described above, the control signals IG, BG, SG, and RG supplied to the scanning lines Sga, Sgb, Sgc, and Sgd drive the pixel circuit PC, and the light-emitting element 10 emits light with a luminance corresponding to the video signal Vsig of the video signal line VL.

The scanning drivers YDR1 and YDR2 supply the control signals IG, BG, SG, and RG to the scanning lines Sga, Sgb, Sgc, and Sgd of each line (a series of sub-pixel SPs arranged in the first direction X) in sequence based on the above-mentioned start pulse signal STV and the clock signal CVK. Furthermore, based on the signal supplied from the controller 5 shown in FIG. 2, the video driver XDR sequentially supplies the video signal Vsig to each video signal line VL.

Here, in the present embodiment, the pixel PX is arranged in the island portion 21 shown in FIG. 3. That is, the light-emitting element 10 and the pixel circuit PC of each sub-pixel SP included in the pixel PX are located on the island portion 21 in the manner surrounded by a chain line in FIG. 4. Furthermore, in the manner surrounded by another chain line in FIG. 4, the scanning lines Sga, Sgb, Sgc, and Sgd, the video signal line VL, the power supply lines SLa and SLb, the reset line Sgr, and the initialization line Sgi are located on one of the line portions 22 and 23.

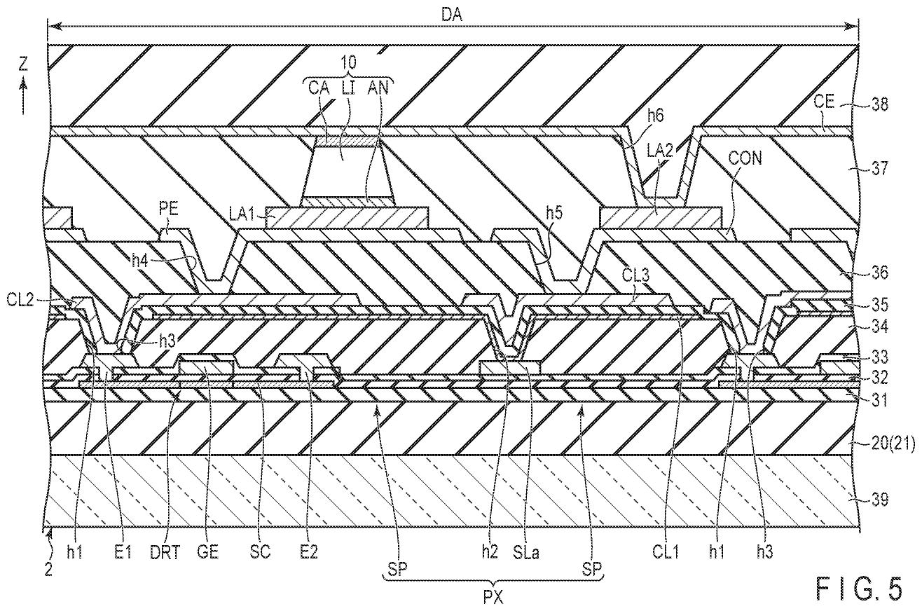

FIG. 5 is a schematic cross-sectional view of the display panel 2. Here, a structure corresponding to a part of the pixel PX (sub-pixel SP) arranged in the island portion 21 in the display area DA is shown.

The display panel 2 comprises the insulating base 20 described above, insulating layers 31, 32, 33, 34, 35, and 36 provided on the insulating base 20, a resin layer 37, a coating layer 38, and a support film 39.

The insulating layer 31 is provided on the insulating base 20. TFTs such as the reset switch RST, the pixel switch SST, the initialization switch IST, the output switch BCT, and the drive transistor DRT shown in FIG. 4 are provided on the insulating layer 31. In FIG. 5, only the drive transistor DRT is shown, and other TFTs are omitted. The drive transistor DRT includes a semiconductor layer SC, a source electrode E1, a drain electrode E2, and a gate electrode GE.

The semiconductor layer SC is provided on the insulating layer 31. The insulating layer 32 covers the insulating layer 31 and the semiconductor layer SC. The gate electrode GE is provided on the insulating layer 32. The insulating layer 33 covers the gate electrode GE and the insulating layer 32. The source electrode E1 and the drain electrode E2 are provided on the insulating layer 33, and are in contact with the semiconductor layer SC through contact holes that penetrate the insulating layers 32 and 33. In the example of FIG. 5, the first power supply line SLa is also provided on the insulating layer 33.

The insulating layer 34 covers the source electrode E1, the drain electrode E2, the first power supply line SLa, and the insulating layer 33. The insulating layer 34 is provided with a contact hole h1 that exposes the upper surface of the source electrode E1 and a contact hole h2 that exposes the upper surface of the first power supply line SLa. A conductive layer CL1 is provided on the insulating layer 34. The conductive layer CL1 is in contact with the first power supply line SLa through the contact hole h2.

The insulating layer 35 covers the conductive layer CL1 and the insulating layer 34. The insulating layer 35 includes a contact hole h3 that overlaps the contact hole h1. Conductive layers CL2 and CL3 are provided on the insulating layer 35. The conductive layer CL2 is in contact with the source electrode E1 through the contact holes h1 and h3.

The insulating layer 36 covers the conductive layers CL2 and CL3 and the insulating layer 35. The insulating layer 36 is provided with a contact hole h4 that exposes the conductive layer CL2 and a contact hole h5 that exposes the conductive layer CL3.

A pixel electrode PE and a contact electrode CON are provided on the insulating layer 36. The pixel electrode PE is in contact with the conductive layer CL2 through the contact hole h4. The contact electrode CON is in contact with the conductive layer CL3 through the contact hole h5. A connection layer LA1 is provided on the pixel electrode PE, and a connection layer LA2 is provided on the contact electrode CON.

The light-emitting element 10 is provided on the connection layer LA1. The light-emitting element 10 comprises an anode AN, a cathode CA, and a light-emitting layer LI disposed between the anode AN and the cathode CA. The light-emitting layer LI emits light in response to the potential difference between the anode AN and the cathode CA. The anode AN is in contact with the upper surface of the connection layer LA1.

The resin layer 37 covers the connection layers LA1 and LA2, and fills a gap between a plurality of light-emitting elements 10. The cathode CA is exposed from the resin layer 37. A contact hole h6 that exposes the connection layer LA2 is provided on the resin layer 37.

The resin layer 37 is covered with a common electrode CE. The common electrode CE is arranged, for example, to overlap the entire island portion 21, but is not provided on the line portions 22 and 23. The common electrode CE is in contact with the connection layer LA2 through the contact hole h6. The common electrode CE is also in contact with the cathode CA.

The coating layer 38 covers the common electrode CE. The support film 39 covers a bottom surface of the insulating base 20. These coating layer 38 and support film 39 are provided over the entire display panel 2.

The insulating layers 31, 32, 33, and 35 are formed of inorganic insulating materials such as silicon oxide (SiO) and silicon nitride (SiN). The insulating layers 34 and 36 are formed of an organic insulating material such as a photosensitive acrylic resin. The insulating layers 34 and 36 are thicker than the insulating layers 31, 32, 33, and 35 and function as a planarization layer.

The source electrode E1, the drain electrode E2, and the first power supply line SLa are located in the same layer and are formed of the same metallic material. As this metallic material, for example, a titanium-based (Ti), aluminum-based (Al), and titanium-based (Ti) three-layer stacked structure can be applied.

The conductive layer CL1 is formed of a transparent conductive material such as indium tin oxide (ITO). The conductive layers CL2 and CL3, the pixel electrode PE, and the contact electrode CON are formed of a metallic material. As this metallic material, for example, a titanium-based (Ti) and aluminum-based (Al) two-layer stacked structure can be applied.

The connection layers LA1 and LA2 are formed of, for example, solder. The common electrode CE is formed of a transparent conductive material such as ITO. The coating layer 38 is formed of, for example, parylene (polyparaxylene) or silicon having an inorganic siloxane bond in the main chain and an organic bond in the side chain. The support film 39 may be formed by applying a resin material to a lower surface of the insulating base 20, or may be attached thereto via an adhesive layer.

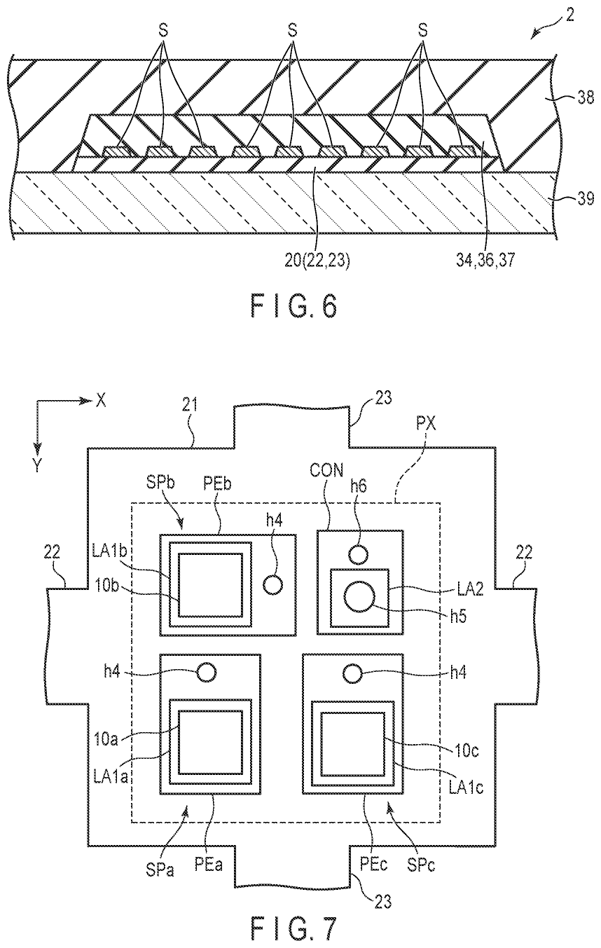

FIG. 6 is a schematic cross-sectional view of a part of the display panel 2 including the first line portion 22. The cross-section of the display panel 2 including the second line portion 23 is also similar to FIG. 6. A plurality of lines S arranged in parallel in the same layer are disposed on the line portions 22 and 23. These lines S are, for example, the scanning lines Sga, Sgb, Sgc, and Sgd, the video signal line VL, the power supply lines SLa and SLb, the reset line Sgr, and the initialization line Sgi described above; however, may also include other lines.

The line portions 22 and 23 are easily deformed as the display panel 2 expands, contracts or bends. If insulating layers formed of inorganic insulating materials are present in the line portions 22 and 23, the insulating layers may be damaged due to deformation. If the lines S are disposed on these insulating layers, the lines S may also be damaged along with the insulating layers. Therefore, in the example of FIG. 6, insulating layers formed of inorganic insulating materials, such as insulating layers 31, 32, 33, and 35, are not provided on the line portions 22 and 23.

The line portions 22 and 23 and the lines S are covered by the insulating layers 34 and 36 and the resin layer 37. For example, the insulating layers 34 and 36 and the resin layer 37 are also patterned in the same shape as the insulating base 20 shown in FIG. 3.

The coating layer 38 and the support film 39 are also provided on portions of the display panel 2 that correspond to the line portions 22 and 23 and portions where the island portion 21 and the line portions 22 and 23 do not exist. In the portions where the island portion 21 and the line portions 22 and 23 do not exist, the coating layer 38 and the support film 39 may be in contact in the manner shown in FIG. 6, or some insulating layer may be interposed between the coating layer 38 and the support film 39. The coating layer 38 and the support film 39 are preferably formed of a material having excellent flexibility and elasticity so as not to impair the flexibility and elasticity of the display panel 2.

Details of the structure of the pixel PX will now be described.

FIG. 7 is a schematic plan view of some elements included in the pixel PX. In the present embodiment, a case where the pixel PX includes three sub-pixels SPa, SPb, and SPc, and the light-emitting element 10 of these sub-pixels SPa, SPb, and SPc and the pixel circuit PC are arranged in the island portion 21 is assumed. The sub-pixel SPa displays a first color, the sub-pixel SPb displays a second color, and the sub-pixel SPc displays a third color. As an example, the first color is red, the second color is green, and the third color is blue. However, the pixel PX may include sub-pixels that display other colors such as white.

The sub-pixels SPa, SPb, and SPc have the structures shown in FIG. 4 and FIG. 5. In FIG. 7, the shapes of the pixel electrodes PE (PEa, PEb, and PEc) of each sub-pixel SPa, SPb, and SPc, the connection layer LA1 (LA1a, LA1b, and LA1c), and the light emitting element 10 (10a, 10b, and 10c), the shapes of the contact electrode CON and the connection layer LA2, and the locations of the contact holes h4, h5, and h6 are shown. All of these elements are arranged in the island portion 21.

In the example of FIG. 7, the pixel electrode PEa of the sub-pixel SPa and the pixel electrode PEc of the sub-pixel SPc are aligned in the first direction X, and the pixel electrode PEb of the sub-pixel SPb and the contact electrode CON are aligned in the first direction X. Furthermore, the pixel electrode PEa and the pixel electrode PEb are aligned in the second direction Y, and the pixel electrode PEc and the contact electrode CON are aligned in the second direction Y. For example, the pixel electrodes PEa, PEb, and PEc and the contact electrode CON are rectangular; however, the shape is not limited thereto.

The connection layer LAla of the sub-pixel SPa is disposed on the pixel electrode PEa, the connection layer LA1b of the sub-pixel SPb is disposed on the pixel electrode PEb, the connection layer LA1c of sub-pixel SPc is disposed on the pixel electrode PEc, and the connection layer LA2 is disposed on the contact electrode CON.

The light-emitting element 10a of the sub-pixel SPa is disposed on the connection layer LA1a, the light-emitting element 10b of the sub-pixel SPb is disposed on the connection layer LA1b, and the light-emitting element 10c of the sub-pixel SPc is disposed on the connection layer LA1c.

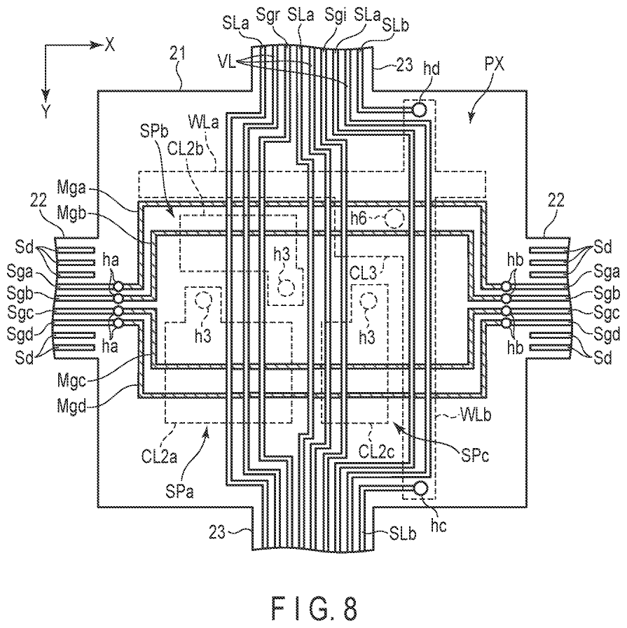

FIG. 8 is a schematic plan view of other elements included in the pixel PX. The drawing shows the shape of the conductive layers CL2 (CL2a, CL2b, and CL2c) of the sub-pixels SPa, SPb, and SPc, the shape of the conductive layer CL3, the shape of various lines, and the locations of the contact holes h3 and h6.

The conductive layer CL2a of the sub-pixel SPa, the conductive layer CL2b of the sub-pixel SPb, and the conductive layer CL2c of the sub-pixel SPc are located below the pixel electrodes PEa, PEb, and PEc shown in FIG. 7, respectively.

In the example of FIG. 8, the pixel PX further comprises a line WLa extending in the first direction X and a line WLb extending in the second direction Y. These lines WLa and WLb are connected to each other and are formed by the conductive layer CL3. The lines WLa and WLb are formed in the same layer and of the same material as the conductive layers CL2a, CL2b, and CL2c.

On the first line portion 22, the scanning lines Sga, Sgb, Sgc, and Sgd and a plurality of dummy lines Sd are disposed. The scanning lines Sga, Sgb, Sgc, and Sgd are examples of a first line in the present embodiment.

The dummy lines Sd are lines that are not connected to the pixel circuit PC and do not extend to the island portion 21. In the example of FIG. 8, three dummy lines Sd are disposed near one end of the first line portion 22 in the second direction Y, two dummy lines Sd are disposed near the other end, and the scanning lines Sga, Sgb, Sgc, and Sgd are disposed between them. The scanning lines Sga, Sgb, Sgc, and Sgd and a plurality of dummy lines Sd are lined up in the same layer as the lines S shown in FIG. 6.

On the second line portion 23, three first power supply lines SLa, three video signal lines VL, the second power supply line SLb, the reset line Sgr, and the initialization line Sgi are disposed. The three first power supply lines SLa, the three video signal lines VL, the second power supply line SLb, the reset line Sgr, and the initialization line Sgi are examples of a second line in the present embodiment.

The three first power supply lines SLa supply a high voltage potential Pvdd to the sub-pixels SPa, SPb, and SPc, respectively. The three video signal lines VL supply a video signal Vsig to the sub-pixels SPa, SPb, and SPc, respectively. The three first power supply lines SLa, the three video signal lines VL, the second power supply line SLb, the reset line Sgr, and the initialization line Sgi are lined up in the same layer as the line S shown in FIG. 6.

In the present embodiment, the number of lines arranged in the first line portion 22 (sum of the number of scanning lines Sga, Sgb, Sgc, and Sgd and the number of dummy lines) and the number of lines arranged in the second line portion 23 are both the same (nine lines). That is, the dummy lines Sd are provided to match the number of lines in the first line portion 22 with the number of lines in the second line portion 23.

In the present embodiment, the scanning lines Sga, Sgb, Sgc, and Sgd, the power supply lines SLa and SLb, the video signal line VL, the reset line Sgr, the initialization line Sgi, and the dummy lines Sd are formed in the same layer and of the same metallic material. The layer in which these lines are arranged is, for example, a layer between the insulating layers 33 and 34 in the structure of the island portion 21 shown in FIG. 5. Furthermore, the scanning lines Sga, Sgb, Sgc, and Sgd and the second power supply line SLb are connected to lines of other layers in the island portion 21.

Specifically, the scanning lines Sga, Sgb, Sgc, and Sgd are connected to relay lines Mga, Mgb, Mgc, and Mgd disposed respectively on the island portion 21. The relay lines Mga, Mgb, Mgc, and Mgd are disposed between, for example, the insulating layers 32 and 33. That is, the relay lines Mga, Mgb, Mgc, and Mgd pass under the first power supply line SLa, the video signal line VL, the reset line Sgr, and the initialization line Sgi.

One end of the relay lines Mga, Mgb, Mgc, and Mgd is connected respectively to the scanning lines Sga, Sgb, Sgc, and Sgd of the first line portion 22 on the left side of the drawing through a contact hole ha provided in the insulating layer 33. The other end of the relay lines Mga, Mgb, Mgc, and Mgd is connected respectively to the scanning lines Sga, Sgb, Sgc, and Sgd of the first line portion 22 on the right side of the drawing through a contact hole hb provided in the insulating layer 33. Both of these contact holes ha and hb are located on the island portion 21.

The three first power supply lines SLa, the three video signal lines VL, the reset line Sgr, and the initialization line Sgi extend over the two second line portions 23 connected to the island portion 21 without changing layers.

The second power supply line SLb of the second line portion 23 in the lower part of the drawing is connected to one end of the line WLb through a contact hole hc. The second power supply line SLb of the second line 23 in the upper part of the drawing is connected to the other end of the line WLb through a contact hole hd. As a result, a low potential Pvss of the second power supply line SLb is supplied to the lines WLa and WLb. The contact holes hc and hd penetrate through, for example, the insulating layers 34 and 35 shown in FIG. 5, and are both located on the island portion 21.

In the example of FIG. 8, the width of a bundle of the scanning lines Sga, Sgb, Sgc, and Sgd and the five dummy lines Sd in the first line portion 22 in the second direction Y is smaller than the width of a bundle of the relay lines Mga, Mgb, Mgc, and Mgd in the island portion 21 in the second direction Y.

In addition, the width of a bundle of the three first power supply lines SLa, the three video signal lines VL, the second power supply line SLb, the reset line Sgr, and the initialization line Sgi in the second line portion 23 in the first direction X is smaller than the width of a bundle of these lines in the island portion 21 in the first direction X.

Subsequently, the structure in the non-display area NDA is explained using an example of the first scanning driver YDR1.

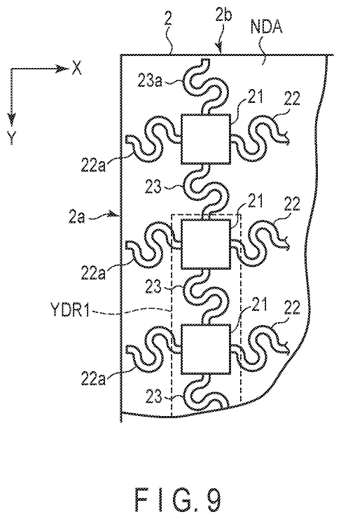

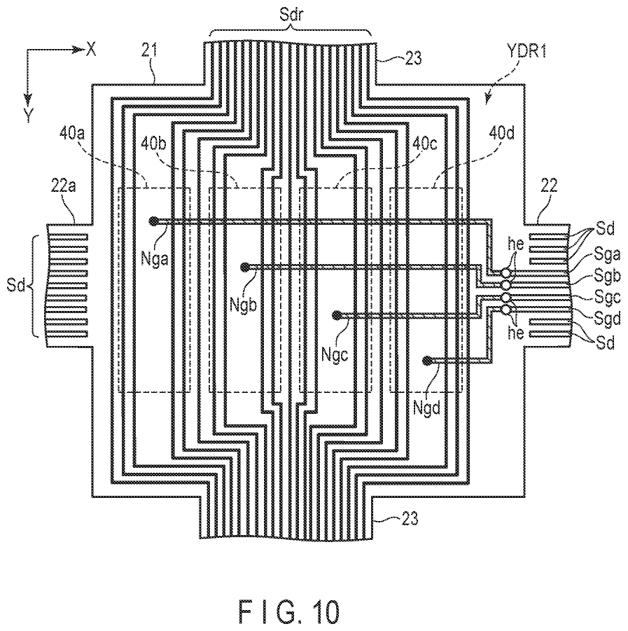

FIG. 9 is a schematic plan view showing a part of the insulating base 20 in the non-display area NDA in an enlarged manner. In the non-display area NDA, the insulating base 20 also includes a plurality of island portions 21 and a plurality of line portions 22 and 23.

For example, the shapes of the island portion 21 (first island portion) and the line portions 22 and 23 arranged in the display area DA, and the shapes of the island portion 21 (second island portion) and the line portions 22 and 23 arranged in the non-display area NDA are the same. However, the shapes of the island portions 21 and the line portions 22 and 23 may differ between the display area DA and the non-display area NDA. In order to realize uniform flexibility and elasticity over the entire display panel 2, the shapes of the island portions 21 and the line portions 22 and 23 are preferred to be the same between the display area DA and the non-display area NDA.

The first scanning driver YDR1 is disposed on a plurality of island portions 21. In this case, the first scanning driver YDR1 may be disposed on one row of island portions 21 lined up in the second direction Y as shown in FIG. 9, or on two or more rows of island portions 21.

Between the island portion 21 closest to an end portion 2a (end portion of the display device 1) of the display panel 2 in the first direction X and the end portion 2a, a first line portion 22 connected to the island portion 21 (hereinafter, referred to as a first line portion 22a) is disposed. Between the island portion 21 closest to an end portion 2b (end portion of the display device 1) of the display panel 2 in the second direction Y and the end portion 2b, a second line portion 23 connected to the island portion 21 (hereinafter, referred to as a second line portion 23a) is disposed.

FIG. 10 is a schematic plan view showing an example of a structure of the first scanning driver YDR1. The first scanning driver YDR1 includes a plurality of first drive circuits 40a, a plurality of second drive circuits 40b, a plurality of third drive circuits 40c, and a plurality of fourth drive circuits 40d. These drive circuits 40a, 40b, 40c, and 40d are arranged one by one with respect to the island portion 21 corresponding to the first scanning driver YDR1. The first scanning driver YDR1 includes shift register circuits, etc., in addition to the drive circuits 40a, 40b, 40c, and 40d.

The first drive circuit 40a outputs a control signal IG to the first scanning line Sga. The second drive circuit 40b outputs a control signal BG to the second scanning line Sgb. The third drive circuit 40c outputs a control signal SG to the third scanning line Sgc. The fourth drive circuit 40d outputs a control signal IG to the fourth scanning line Sgd. In FIG. 10, the drive circuits 40a, 40b, 40c, and 40d are lined up in the first direction X; however, the arrangement of the drive circuits 40a, 40b, 40c, and 40d is not limited to this example.

In the island part 21, relay lines Nga, Ngb, Ngc, and Ngd are arranged. The relay lines Nga, Ngb, Ngc, and Ngd are disposed, for example, between the insulating layers 32 and 33 shown in FIG. 5. Each of the ends of the relay lines Nga, Ngb, Ngc, and Ngd is connected respectively to the drive circuits 40a, 40b, 40c, and 40d. Each of the other ends of the relay lines Nga, Ngb, Ngc, and Ngd is connected respectively to the scanning lines Sga, Sgb, Sgc, and Sgd of the first line portion 22 through contact holes he provided on the insulating layer 33. All of these contact holes he are located on the island portion 21.

In the second line portion 23, a line group Sdr for controlling the drive circuits 40a, 40b, 40c, and 40d is arranged. The line group Sdr includes, for example, power supply lines SLa and SLb, lines to which the above-mentioned start pulse signal STV is supplied, lines to which the above-mentioned clock signal CKV is supplied, and the like. The drive circuits 40a, 40b, 40c, and 40d include a plurality of TFTs that operate based on the signals supplied to each line in the line group Sdr.

The line group Sdr extends over the island portion 21 and two second line portions 23 connected to this island portion 21 without changing layers. The layer in which these lines are arranged is, for example, a layer between the insulating layers 33 and 34 in the structure of the island portion 21 shown in FIG. 5. That is, the relay lines Nga, Ngb, Ngc, and Ngd pass under the line group Sdr. In the present embodiment, the scanning lines Sga, Sgb, Sgc, and Sgd, the dummy lines Sd, and the line group Sdr are formed in the same layer and of the same metallic material. However, at least some of these lines may be arranged in different layers. Also, at least some of these lines may be formed of different materials.

In the example of FIG. 10, the width of a bundle of the scanning lines Sga, Sgb, Sgc, and Sgd and the five dummy lines Sd in the first line portion 22 in the second direction Y is smaller than the width of a bundle of the relay lines Nga, Ngb, Ngc, and Ngd in the island portion 21 in the second direction Y.

Furthermore, the width of the line group Sdr in the second line portion 23 in the first direction X is smaller than the width of the line group Sdr in the island portion 21 in the first direction X. The line group Sdr is arranged at regular intervals in the second line portion 23, but is sparse and dense in the island portion 21.

In the first line portion 22a located at the farthest end, for example, the dummy lines Sd are arranged in the same number as the number of scanning lines Sga, Sgb, Sgc, and Sgd and the dummy lines Sd arranged in the other first line portion 22 (nine in FIG. 10). That is, only the lines that are not connected to Nga, Ngb, Ngc, and Ngd are arranged in the first line portion 22a.

In the example of FIG. 10, the number of lines included in the line group Sdr arranged in the second line portion 23 is larger than the number of scanning lines Sga, Sgb, Sgc, and Sgd and dummy lines Sd arranged in the first line portion 22. As another example, the number of lines of the line portions 22 and 23 may be made the same by increasing the number of dummy lines Sd arranged in the first line portion 22.

The same structure as that of the first scanning driver YDR1 can be applied to the second scanning driver YDR2. Furthermore, the video driver XDR may be configured by a drive circuit arranged in a plurality of island portions 21.

The drive circuits 40a, 40b, 40c, and 40d may be distributed and arranged in the scanning drivers YDR1 and YDR2. For example, the drive circuits 40a and 40b may be arranged in the island portion 21 at a location corresponding to the first scanning driver YDR1, and the drive circuits 40c and 40d may be arranged in the island portion 21 at a location corresponding to the second scanning driver YDR2.

In the present embodiment described above, since the insulating base 20 is configured by the island portion 21 and the non-linear line portions 22 and 23, the display panel 2 can be made flexible and elastic in the manner described above. As a result, it is possible to transform the display panel 2 into, for example, spherical or other three-dimensional curved surfaces.

Furthermore, the pixel circuit PC of each pixel PX (sub-pixel SP) is arranged in the island portion 21. The deformation of the display panel 2 is mainly realized by the line portions 22 and 23, and the island portion 21, which is wider than the line portions 22 and 23, is difficult to deform. Therefore, damage to the pixel circuit PC caused by deformation of the display panel 2 can be suppressed.

In the line portions 22 and 23, a plurality of lines are arranged in parallel in the same layer. This makes the line portions 22 and 23 easier to deform. Furthermore, as shown in FIG. 8, if the number of lines in the line portions 22 and 23 of the display area DA is the same, the directional dependence of deformation can be suppressed. If the lines of the line portions 22 and 23 are located in the same layer as described above and are made of the same metallic material, the directional dependence of the deformation can be more preferably suppressed.

In the present embodiment, as shown in FIG. 8, the contact holes ha and hb for connecting the scanning lines Sga, Sgb, Sgc, and Sgd to the relay lines Mga, Mgb, Mgc, and Mgd are arranged in the island portion 21. In such a configuration, for example, the load due to deformation is less likely to be applied to the contact holes ha and hb compared to the case where contact holes ha and hb are provided in the line portions 22 and 23. Therefore, reliability of conduction can be improved. The same applies to the contact hole he and hd shown in FIG. 8 and the contact hole he shown in FIG. 10. In addition, since the connection portion (connection layer LA1) between the light-emitting element 10 and the pixel circuit PC is also arranged in the island portion 21, the reliability of conduction between the light-emitting element 10 and the pixel circuit PC can also be improved.

As shown in FIG. 9 and FIG. 10, if the first scanning driver YDR1, etc., provided in the non-display area NDA is also configured by the island portion 21 and the line portions 22 and 23, the same flexibility and elasticity as in the display area DA can be given to the non-display area NDA.

The terminal area MT shown in FIG. 1 may also be configured by the island portion 21 and the line portions 22 and 23. In this case, for example, a terminal for connecting to the first circuit board 3 may be arranged in the island portion 21. With this configuration, the terminal area MT can be given the same flexibility and elasticity as the display area DA.

In addition to the above, various other preferable effects can be obtained from the present embodiment.

### Second Embodiment

A second embodiment will be described. The configuration and effects not specifically mentioned are the same as those of the first embodiment.

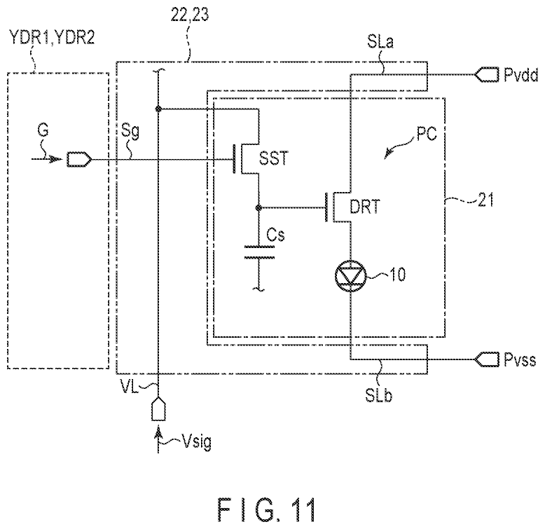

FIG. 11 shows an example of an equivalent circuit of a sub-pixel SP according to the present embodiment. As in the first embodiment, the sub-pixel SP comprises a light-emitting element 10 and a pixel circuit PC that drives the light-emitting element 10. However, the pixel circuit PC includes a pixel switch SST, a drive transistor DRT, and a holding capacitance Cs, but does not include a reset switch RST, an initialization switch IST, an output switch BCT, and an auxiliary capacitance Cad.

A display device 1 according to the present embodiment includes a scanning line Sg instead of scanning lines Sga, Sgb, Sgc, and Sgd shown in FIG. 4. A control signal G is supplied to the scanning line Sg from drive circuits of scanning drivers YDR1 and YDR2. Furthermore, the display device 1 according to the present embodiment does not include an initialization line Sgi and a reset line Sgr.

A drain electrode of the drive transistor DRT is connected to a first power supply line SLa. A source electrode of the drive transistor DRT is connected to one electrode (here, an anode) of the light-emitting element 10. The other electrode of the light-emitting element 10 (here, a cathode) is connected to a second power supply line SLb. The drive transistor DRT outputs a drive current corresponding to a video signal Vsig to the light-emitting element 10.

A source electrode of the pixel switch SST is connected to a video signal line VL. A drain electrode of the pixel switch SST is connected to a gate electrode of the drive transistor DRT. A gate electrode of the pixel switch SST is connected to the scanning line Sg that functions as a gate line for a signal writing control. The pixel switch SST is turned ON and OFF by the control signal G supplied from the scanning line Sg, and switches between connection and disconnection between the pixel circuit PC and the video signal line VL. That is, when the pixel switch SST is turned ON, the video signal Vsig of the video signal line VL is taken into the pixel circuit PC.

Also in the present embodiment, the pixel circuit PC is also located in an island portion 21, as shown by the chain line in FIG. 11. In addition, as surrounded by other chain lines in FIG. 11, the scanning line Sg, the video signal line VL, and the power supply lines SLa and SLb are located in one of a first line portion 22 and a second line portion 23.

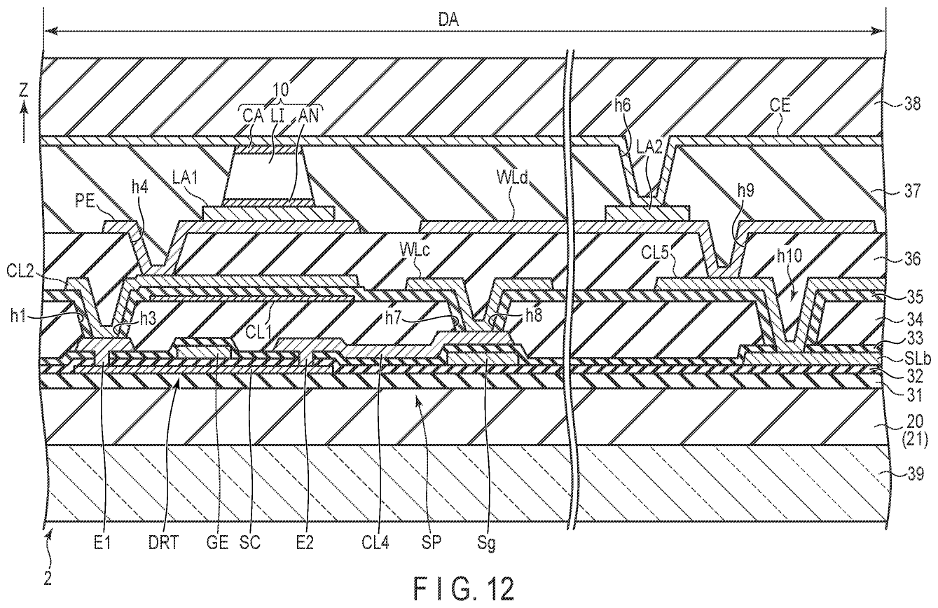

FIG. 12 shows a schematic cross-sectional view of a display panel 2 according to the present embodiment. As in the example shown in FIG. 5, the display panel 2 comprises an insulating base 20, insulating layers 31, 32, 33, 34, 35, and 36, a resin layer 37, a coating layer 38, a support film 39, a pixel electrode PE, a common electrode CE, the light-emitting element 10, conductive layers CL1 and CL2, connection layers LA1 and LA2, and the drive transistor DRT, etc.

In the example of FIG. 12, a drain electrode E2 of the drive transistor DRT is a part of a conductive layer CL4. The conductive layer CL4 is provided on the insulating layer 33 and is covered by the insulating layer 34. The insulating layer 34 has a contact hole h7 at a location overlapping the conductive layer CL4 in the third direction Z. Furthermore, the insulating layer 35 has a contact hole h8 overlapping the contact hole h7. A line WLc is provided on the insulating layer 35 and is in contact with the conductive layer CL4 through the contact holes h7 and h8. A high potential Pvdd is applied to the line WLc via the drive transistor DRT.

The scanning line Sg is provided between the insulating layers 32 and 33. In addition, a line WLd is provided between the insulating layer 36 and the resin layer 37. The lines WLc and WLd and the scanning line Sg overlap in the third direction Z. The connection layer LA2 is provided on the line WLd.

A conductive layer CL5 is provided between the insulating layers 35 and 36. The insulating layer 36 has a contact hole h9 at a location overlapping the line WLd. The line WLd is in contact with the conductive layer CL5 through the contact hole h9.

Furthermore, a part of the second power supply line SLb is provided between the insulating layers 32 and 33. A contact hole h10 that penetrates the insulating layers 33, 34, and 35 is provided at a location overlapping the conductive layer CL5. The conductive layer CL5 is in contact with the second power supply line SLb through this contact hole h10. In this configuration, a low potential Pvss of the second power supply line SLb is supplied to the common electrode CE via the conductive layer CL5, the line WLd, and the connection layer LA2.

The conductive layers CL2 and CL5 and the line WLc are located in the same layer and are formed of the same metallic material. The line WLd and the pixel electrode PE are located in the same layer and are formed of the same metallic material.

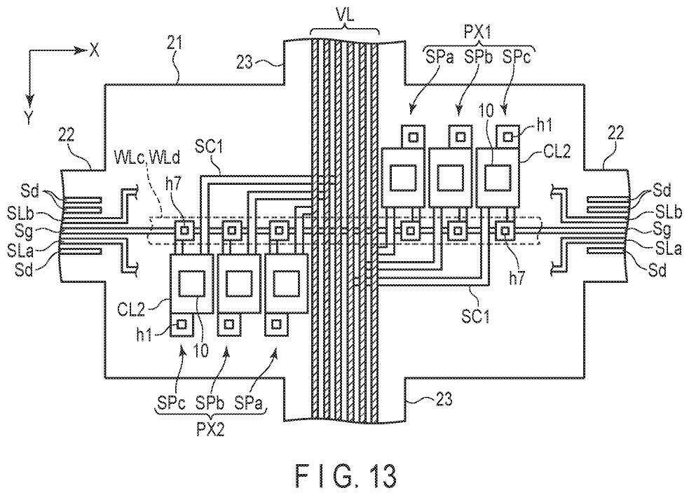

FIG. 13 is a schematic plan view of some of the elements included in the pixel PX. In the present embodiment, two pixels PX (pixels PX1 and PX2) are arranged in the island portion 21. These pixels PX1 and PX2 include three sub-pixels SPa, SPb, and SPc. The sub-pixel SPa displays a first color, the sub-pixel SPb displays a second color, and the sub-pixel SPc displays a third color. As an example, the first color is red, the second color is green, and the third color is blue. However, the pixels PX1 and PX2 may also include sub-pixels that display other colors such as white. Furthermore, the pixels PX1 and PX2 may also include sub-pixels of different color combinations.

In FIG. 13, among the elements configuring the sub-pixels SPa, SPb, and SPc, the light-emitting element 10, the conductive layer CL2, the contact holes h1 and h7, and a semiconductor layer SC1 of the pixel switch SST are shown. The semiconductor layer SC1 is located in the same layer as the semiconductor layer SC of the drive transistor DRT shown in FIG. 12.

The sub-pixels SPa, SPb, and SPc of the pixel PX1 are arranged in the upper right part of the drawing of the island portion 21, and the sub-pixels SPa, SPb, and SPc of the pixel PX2 are arranged in the lower left part of the drawing of the island portion 21. That is, the pixels PX1 and PX2 are arranged in a diagonal direction of the island portion 21. In each of the pixels PX1 and PX2, the conductive layers CL2 and the light-emitting elements 10 of the sub-pixels SPa, SPb, and SPc are lined up in the first direction X.

Six video signal lines VL corresponding to each of the sub-pixels SPa, SPb, and SPc are disposed between the pixels PX1 and PX2. These video signal lines VL are all located in the same layer and extend in the second direction Y over the island portion 21 and two second line portions 23 connected to this island portion 21 without changing layers. Each of the semiconductor layers SC1 of each of the sub-pixel SPa, SPb, and SPc is connected to a corresponding video signal line VL.

In addition, the scanning line Sg and lines WLc and WLd are disposed between the pixels PX1 and PX2. The scanning line Sg extends in the first direction X over the island portion 21 and two first line portions 22 connected to this island portion 21 without changing layers. The lines WLc and WLd overlap the scanning line Sg and extend in the first direction X. Each sub-pixel SPa, SPb, and SPc is connected to the line WLc through the contact hole h7.

In the first line portion 22, the scanning line Sg and the power supply lines SLa and SLb are arranged. Furthermore, in the example of FIG. 13, three dummy lines Sd are arranged in the first line portion 22. The scanning line Sg, the power supply lines SLa and SLb, and the plurality of dummy lines Sd are all located in the same layer.

Note that, in the island portion 21, the video signal line VL and the scanning line Sg and the power supply lines SLa and SLb are located in different layers. That is, the video signal line VL is located between the insulating layers 33 and 34 in FIG. 12, and the scanning line Sg and the power supply lines SLa are SLb are located between the insulating layers 32 and 33 in FIG. 12. In the case where the insulating layer 33 is not provided in the line portions 22 and 23 as shown in FIG. 6, the video signal line VL, the scanning line Sg, and the power supply lines SLa and SLb are all located between the insulating base 20 and the insulating layer 34 in the line portions 22 and 23.

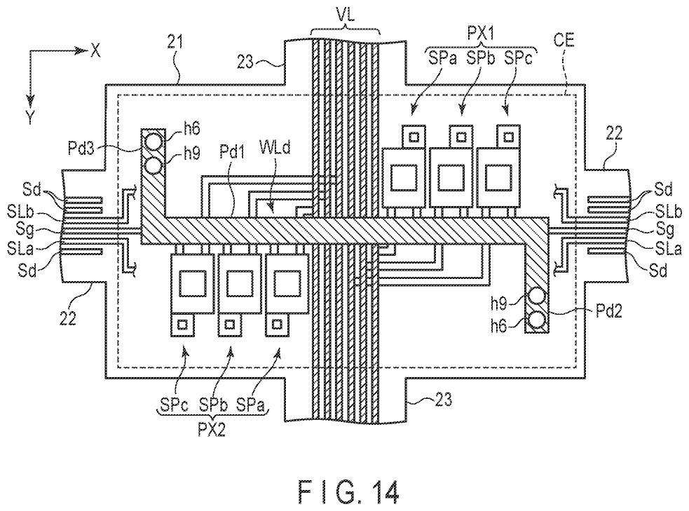

FIG. 14 is a plan view showing an example of the shapes of the line WLd and the common electrode CE. The common electrode CE has a shape that totally overlaps the island portion 21. The common electrode CE is not provided in the line portions 22 and 23.

The line WLd has a first portion Pd1, a second portion Pd2, and a third portion Pd3. The first portion Pd1 overlaps the scanning line Sg and extends in the first direction X. The second portion Pd2 is connected to an end of the first portion Pd1 on the pixel PX1 side and extends in the second direction Y away from the pixel PX1. The third portion Pd3 is connected to an end of the first portion Pd1 on the pixel PX2 side and extends in the second direction Y away from the pixel PX2.

The contact holes h6 and h9 described above are provided at locations overlapping with the second and third portions Pd2 and Pd3. The line WLd and the common electrode CE are connected through each contact hole h6.

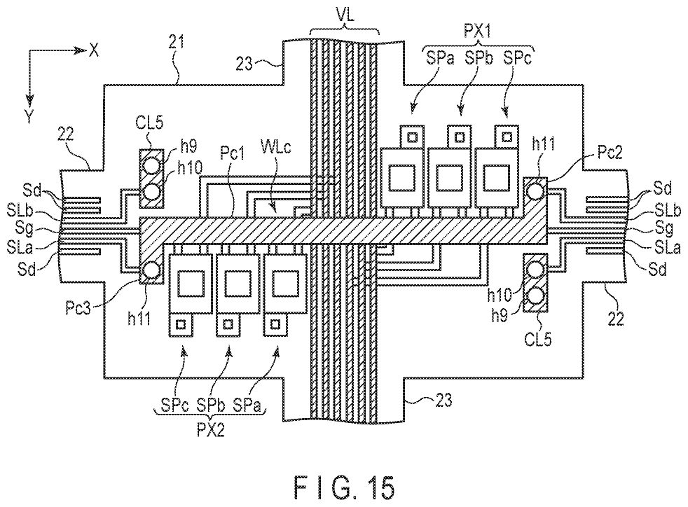

FIG. 15 is a plan view showing an example of the shapes of the line WLc and the conductive layer CLS. The line WLc has a first portion Pc1, a second portion Pc2, and a third portion Pc3. The first portion Pc1 overlaps the scanning line Sg and extends in the first direction X. The second portion Pc2 is connected to an end of the first portion Pc1 on the pixel PX1 side and extends in the second direction Y on the side of the pixel PX1. The third portion Pc3 is connected to an end of the first portion Pc1 on the pixel PX2 side and extends in the second direction Y on the side of pixel PX2.

Contact holes h11 are provided at locations overlapping the second portion Pct and the third portion Pc3, respectively. The contact holes h11 penetrate the insulating layers 33, 34, and 35 shown in FIG. 12. The first power supply line SLa arranged in each of a pair of first line portions 22 is located between the insulating layers 32 and 33 in the island portion 21. The line WLc is connected to these first power supply lines SLa through each of the contact holes h11.

The conductive layer CL5 is arranged at each location overlapping the second portion Pd2 and the third portion Pd3 of the line WLd shown in FIG. 14. Each conductive layer CL5 is connected to the line WLd through the contact hole h9. Furthermore, the contact hole h10 described above is provided at a location overlapping each conductive layer CL5. Each of the conductive layers CL5 is connected to the second power supply line SLb arranged in each of the pair of first line portions 22 through the contact holes h10.

Thus, by reconnecting the power supply lines SLa and SLb to the lines WLd and WLc of other layers in the island portion 21, an efficient pixel layout can be realized even in a case where a plurality of pixels PX are arranged in the island portion 21. In addition, the present embodiment has the same effect as that of the first embodiment.

Note that, although the example of connecting the line WLd and the second power supply line SLb via the conductive layer CL5 is shown in the present embodiment, the line WLd and the second power supply line SLb may also be directly connected.

### Third Embodiment

A third embodiment will be described. The configuration and effects not specifically mentioned are the same as those of the first embodiment.

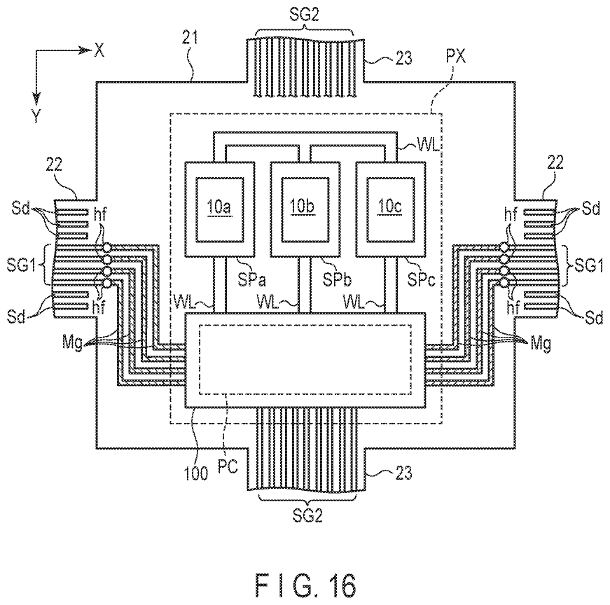

FIG. 16 is a schematic plan view of a pixel PX according to the present embodiment. In the present embodiment, the pixel PX comprises an integrated circuit 100 (IC) including a pixel circuit PC. The integrated circuit 100 is mounted on an island portion 21.

As in the first embodiment, the pixel PX includes sub-pixels SPa, SPb, and SPc. Light-emitting elements 10a, 10b, and 10c of the sub-pixels SPa, SPb, and SPc are connected to the integrated circuit 100 by a line WL provided in the island portion 21.

A first line group SG1 is arranged in a first line portion 22. A second line group SG2 is arranged in a second line portion 23. In the example shown in FIG. 16, the number of lines included in the first line group SG1 is smaller than the number of lines included in the second line group SG2. In order to eliminate this difference in the number of lines, a dummy line Sd is arranged in the first line portion 22.

As another example, the number of lines included in the first line group SG1 may be larger than the number of lines included in the second line group SG2. In this case, the dummy line Sd may be arranged in the second line portion 23 to eliminate the difference in the number of lines.

As shown in FIG. 16, each line of the first line group SG1 may be connected to a relay line Mg in the island portion 21. A contact hole hf connecting each line of the first line group SG1 to the relay line Mg is preferred to be provided in the island portion 21. The second line group SG2 may be similarly connected to the relay line in the island portion 21.

Each line of the first line group SG1 and the second line group SG2 is connected to the integrated circuit 100. The integrated circuit 100 turns ON each of the light-emitting elements 10a, 10b, and 10c based on a drive voltage, control signals, video signals, etc., supplied from these lines.

In the case of driving the pixel PX by the integrated circuit 100 as in the present embodiment, if the mounting portion of the integrated circuit 100 is deformed, a connection failure of the integrated circuit 100 may occur. In the present embodiment, since the integrated circuit 100 is mounted on the island portion 21 which is hard to be deformed, the connection reliability in the mounting portion of the integrated circuit 100 can be improved while realizing a display panel 2 having flexibility and elasticity. In addition, the present embodiment has the same effect as that of the first embodiment.

### Fourth Embodiment

A fourth embodiment will be described. The configuration and effects not specifically mentioned are the same as those of the first embodiment.

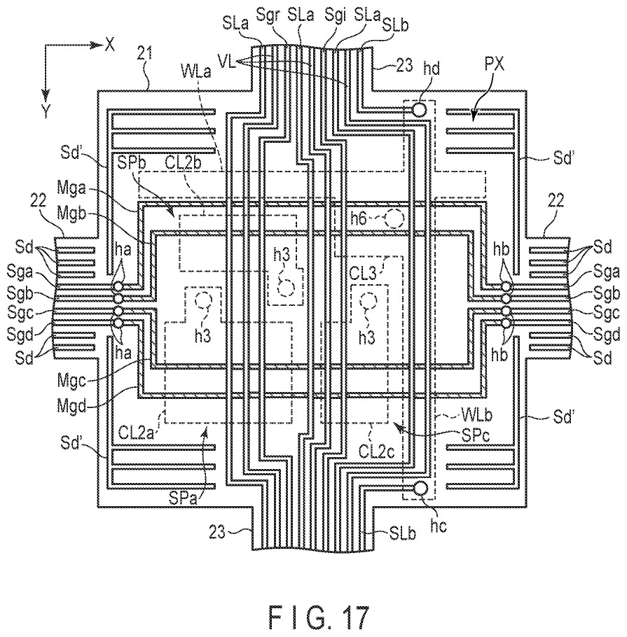

FIG. 17 is a schematic plan view of a pixel PX in the present embodiment. The present embodiment differs from the example of FIG. 8 in that a dummy line Sd′ is formed in an island portion 21. That is, in addition to the dummy lines Sd formed in the first line portion 22 in the example of FIG. 8, in the example of FIG. 17, the dummy line Sd′ is arranged in the island portion 21. In addition, the description of the structure overlapping with the example of FIG. 8 will be omitted.

In the example of FIG. 17, the dummy line Sd′ provided in the island portion 21 is not connected to a pixel circuit PC (see FIG. 4) configuring the pixel PX and various lines and semiconductors, etc., related thereto, and is arranged at a distance from the pixel circuit PC. The dummy line Sd′ is formed at a peripheral portion of the island portion 21, and in an area between a first line portion 22 and a second line portion 23. The dummy line Sd′ may or may not be connected to the dummy line Sd of the first line portion 22. By arranging the dummy line Sd′ on the peripheral portion of the island portion 21, it is possible to suppress the occurrence of distortion in the island portion 21 due to the deformation of the first line portion 22 and the second line portion 23.

In the example of FIG. 17, each of the dummy lines Sd′ has three straight portions extending in the first direction X and one straight portion extending in the second direction Y. However, the shape of each dummy line Sd′ is not limited to this example.

In each of the above embodiments, the case in which one or two pixels PX are arranged in the island portion 21 is illustrated. However, the number of pixels PX arranged in the island portion 21 may be three or more. Furthermore, the sub-pixels SP included in one pixel PX may be dispersed and arranged in a plurality of island portions 21. In this case, only one sub-pixel SP may be arranged for one island portion 21.

Based on the display device which has been described in the above-described embodiments, a person having ordinary skill in the art may achieve a display device with an arbitral design change; however, as long as they fall within the scope and spirit of the present invention, such a display device is encompassed by the scope of the present invention.

A skilled person would conceive various changes and modifications of the present invention within the scope of the technical concept of the invention, and naturally, such changes and modifications are encompassed by the scope of the present invention. For example, if a skilled person adds/deletes/alters a structural element or design to/from/in the above-described embodiments, or adds/deletes/alters a step or a condition to/from/in the above-described embodiment, as long as they fall within the scope and spirit of the present invention, such addition, deletion, and altercation are encompassed by the scope of the present invention.

Furthermore, regarding the present embodiments, any advantage and effect those will be obvious from the description of the specification or arbitrarily conceived by a skilled person are naturally considered achievable by the present invention.

What is claimed is:

1. A display device comprising:
an insulating base including a plurality of first island portions and a plurality of non-linear line portions connecting two of the first island portions;
a plurality of light-emitting elements arranged in each of the first island portions;
a plurality of pixel circuits arranged in each of the first island portions and driving the light-emitting elements; and
a plurality of lines arranged in each of the line portions and connected to the pixel circuits of the two first island portions connected by the line portions.

2. The display device of claim 1, wherein two or more of the lines are arranged in the same layer and in parallel in one of the line portions.

3. The display device of claim 1, wherein
the first island portions are arranged in a first direction and in a second direction intersecting the first direction,
the line portions include a first line portion connecting the first island portions arranged in the first direction and a second line portion connecting the first island portions arranged in the second direction, and
the lines include at least one first line arranged in the first line portion and at least one second line arranged in the second line portion.

4. The display device of claim 3, further comprising at least one dummy line arranged in the first line portion and not connected to the pixel circuits, wherein
a sum of the number of the first lines and the dummy lines arranged in one first line portion is the same as the number of the second lines arranged in one second line portion.

5. The display device of claim 3, further comprising a contact hole connecting the first line to a line in a different layer from the first line in the first island portion.

6. The display device of claim 3, wherein a layer in which the first line is formed in the first line portion and a layer in which the second line is formed in the second line portion are the same.

7. The display device of claim 1, wherein
the insulating base further includes a plurality of second island portions connected to the first island portions via the line portions, and
the display device further comprises a plurality of drive circuits arranged in each of the second island portions and supplying signals for driving the pixel circuits to the lines.

8. The display device of claim 7, wherein the line portions include a line portion having one end connected to the second island portion and extended toward an end portion of the display device, the lines also being arranged in the line portion.

9. The display device of claim 1, wherein a plurality of the light-emitting elements and a plurality of the pixel circuits corresponding to a plurality of sub-pixels are arranged in one first island portion.

10. The display device of claim 1, wherein an integrated circuit including the pixel circuit is mounted on the first island portion.
